(19) United States
(12) Patent Application Publication
(10) Pub. No.: US 2020/0105850 A1
(43) Pub. Date: Apr. 2, 2020

(54) DISPLAY DEVICE

(71) Applicant: Samsung Display Co., Ltd., Yongin-si (KR)

(72) Inventors: Mee Jae Kang, Suwon-si (KR); Joon Woo Bae, Hwaseong-si (KR); Thanh Tien Nguyen, Seoul (KR); Kyoung Won Lee, Seoul (KR); Yong Su Lee, Seoul (KR); Jae Seob Lee, Seoul (KR); Gyoo Chul Jo, Suwon-si (KR); Myoung Geun Cha, Seoul (KR)

(21) Appl. No.: 16/586,135

(22) Filed: Sep. 27, 2019

(30) Foreign Application Priority Data
Sep. 28, 2018 (KR) 10-2018-0115868

(51) Int. Cl. H01L 27/32

(52) U.S. Cl. CPC H01L 27/3262; H01L 27/3258; H01L 27/1222; H01L 27/3272; H01L 27/3276; H01L 27/3265

(57) ABSTRACT

An exemplary embodiment of the present disclosure provides a display device including: a substrate; a semiconductor layer disposed on the substrate; a first transistor including a first gate electrode disposed on the semiconductor layer; a light-emitting diode connected with the first transistor; and a first layer disposed between the substrate and the semiconductor layer, wherein the semiconductor layer includes a first electrode, a second electrode, and a channel disposed between the first electrode and the second electrode, the channel includes an impurity, and the first layer overlaps the first transistor.

### CROSS-REFERENCE TO RELATED APPLICATION

This application claims priority to and benefit of Korean Patent Application No. 10-2018-0115868 filed in the Korean Intellectual Property Office on Sep. 28, 2018, the entire contents of which are incorporated herein by reference.

### BACKGROUND

### (a) Field

The present disclosure relates to a display device.

### (b) Description of the Related Art

A display device is a device that displays an image, and a light emitting diode display has recently been in the spotlight as a self-emissive display device.

Unlike a liquid crystal display (LCD) device, a light emitting diode display has a self-emissive characteristic and eliminates the necessity for a separate light source, and thus can be fabricated to be thinner and lighter. Furthermore, the light emitting diode display has high quality characteristics such as low power consumption, high luminance, high response speed, and the like.

In general, a light emitting diode display includes a substrate, a plurality of thin film transistors located on the substrate, a plurality of insulating layers disposed between the wires constituting the thin film transistors, and light emitting elements connected to the thin film transistors.

The above information disclosed in this Background section is only for enhancement of understanding of the background of the invention and therefore it may contain information that does not form the prior art that is already known in this country to a person of ordinary skill in the art.

### SUMMARY

The present disclosure has been made in an effort to improve an afterimage characteristic and a display characteristic.

An exemplary embodiment of the present disclosure provides a display device including: a substrate; a semiconductor layer disposed on the substrate; a first transistor including a first gate electrode disposed on the semiconductor layer; a light-emitting diode connected with the first transistor; and a first layer disposed between the substrate and the semiconductor layer, wherein the semiconductor layer includes a first electrode, a second electrode, and a channel disposed between the first electrode and the second electrode, the channel includes an impurity, and the first layer overlaps the first transistor.

The first layer may be connected to one of the first electrode and the second electrode.

The display device may include an insulating layer disposed on the first transistor and a data connecting member disposed on the insulating layer, and the first electrode and the first layer may be connected by the data connecting member.

The impurity may include one of boron, aluminum, indium, and gallium.

The first layer may include one of a metal having a conductive characteristic and a semiconductor material having a conductive characteristic that is similar to that of a metal.

The semiconductor layer may include a protrusion.

The channel may include a depletion region and a carrier transport region, the depletion region may be disposed at a lower end of the channel, and the carrier transport region may be disposed at an upper end of the channel.

Cross-sections of the depletion region and the carrier transport region may have shapes that are inclined with reference to the substrate.

An exemplary embodiment of the present disclosure provides a display device including: a substrate; a semiconductor layer disposed on the substrate; a first transistor including a first gate electrode disposed on the semiconductor layer; a light-emitting diode connected with the first transistor; and a first layer disposed between the substrate and the semiconductor layer, wherein the semiconductor layer includes a first electrode, a second electrode, and a channel disposed between the first electrode and the second electrode, the channel includes an impurity, and the first layer receives a constant voltage.

The first layer may receive a driving voltage.

The display device may further include a storage line that overlaps the first gate electrode, and the storage line and the first layer may be connected.

The storage line may receive a driving voltage.

The display device may further include a gate insulating layer disposed between the storage line and the first gate electrode, and the storage line and the first gate electrode may constitute a storage capacitor.

The display device may further include an insulating layer disposed on the storage line and a driving voltage line disposed on the passivation layer, and the driving voltage line may be connected to the storage line through a contact hole.

A second transistor and a third transistor connected to the first transistor may be included, and the first layer may overlap the third transistor.

According to the exemplary embodiment, the afterimage and display characteristics of a display device can be improved.

### BRIEF DESCRIPTION OF THE DRAWINGS

FIG. 1 illustrates a circuit diagram of a pixel of a display device according to an exemplary embodiment.

FIG. 2 schematically illustrates a top plan view of a region of a display device according to an exemplary embodiment.

FIG. 3 illustrates a cross-sectional view taken along a line of FIG. 2.

FIG. 4 illustrates an enlarged schematic cross-sectional view of some constituent elements of FIG. 3.

FIG. 5 illustrates a cross-sectional view showing a step of a manufacturing process of a display device according to an example.

FIG. 6 illustrates a cross-sectional view showing a step of a manufacturing process of a display device according to a comparative example.

FIG. 7 illustrates a circuit diagram of a pixel of a display device according to an exemplary embodiment.

FIG. 8 schematically illustrates a top plan view of a region of a display device according to an exemplary embodiment.

FIG. 9 illustrates a cross-sectional view taken along a line IX-IX′ of FIG. 8.

FIG. 10 illustrates a graph showing hysteresis characteristics for a comparative example and an example.

FIG. 11 illustrates a graph showing afterimage characteristics for a comparative example and an example.

FIG. 12 illustrates a graph showing S-factors for a comparative example and an example.

### DETAILED DESCRIPTION OF THE EMBODIMENTS

The present disclosure will be described more fully hereinafter with reference to the accompanying drawings, in which exemplary embodiments of the invention are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “over” or “on” means positioning on or below the object portion, and does not necessarily mean positioning on the upper side of the object portion based on a gravity direction.

In addition, unless explicitly described to the contrary, the word “comprise” and variations such as “comprises” or “comprising” will be understood to imply the inclusion of stated elements but not the exclusion of any other elements.

Further, in the specification, the phrase “in a plan view” means when an object portion is viewed from above, and the phrase “in a cross-sectional view” means when a cross-section taken by vertically cutting an object portion is viewed from the side.

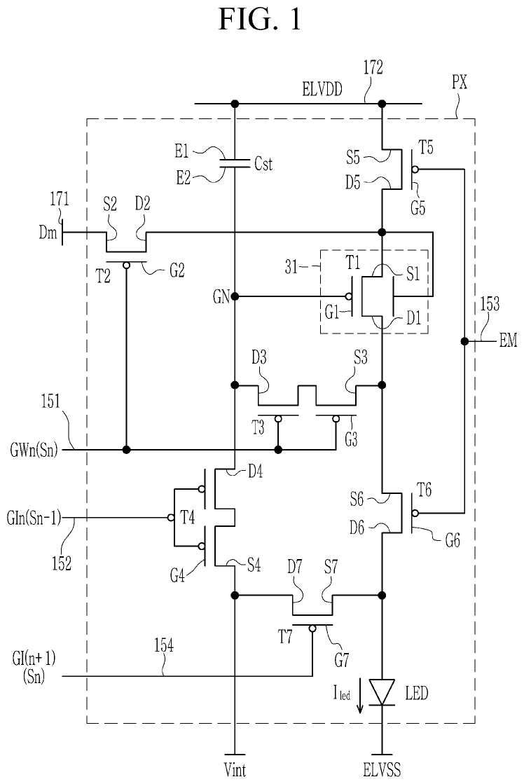

Hereinafter, driving of a pixel will now be described with reference to FIG. 1. FIG. 1 illustrates a circuit diagram of a pixel of a display device according to an exemplary embodiment.

Referring to FIG. 1, according to the present exemplary embodiment, the pixel PX of the display device may include a plurality of signal lines 151, 152, 153, 154, 171, and 172 and a plurality of transistors T1, T2, T3, T4, T5, T6, and T7 connected thereto, a storage capacitor Cst, and a light emitting diode LED. In the present exemplary embodiment, an example in which one pixel PX includes one light emitting diode LED will be mainly described.

The signal lines 151, 152, 153, 154, 171, and 172 may include a plurality of scan lines 151, 152, and 154, a control line 153, a data line 171, and a driving voltage line 172.

The scan lines 151, 152, and 154 may carry scan signals GWn, GIn, and GI(n+1), respectively. The scan signals GWn, Gin, and GI(n+1) may transfer a gate-on voltage and a gate-off voltage that can turn the transistors T2, T3, T4, and T7 included in the pixel PX on or off.

The scan lines 151, 152, and 154 connected to a pixel PX may include a first scan line 151 through which the scan signal GWn can be transferred, a second scan line 152 through which the scan signal GIn having a gate-on voltage can be transferred at a different time from that of the first scan line 151, and a third scan line 154 through which the scan signal GI(n+1) can be transferred. The second scan line 152 may transfer the gate-on voltage at a time that is earlier than that of the first scan line 151. For example, when a scan signal GWn is an n^{th} scan signal Sn (n being a natural number that is equal to or greater than 1) among the scan signals applied during one frame, a scan signal GIn may be a previous-stage scan signal such as an (n−1)^{th}, and the scan signal GI(n+1) may be an n^{th} scan signal Sn. However, the present exemplary embodiment is not limited thereto, and the scan signal GI(n+1) may be a scan signal that is different from the nth scan signal Sn.

The control line 153 may transfer a light emission control signal EM, and particularly a light emission control signal capable of controlling light emission of a light-emitting diode LED included in the pixel PX.

The data line 171 may transfer a data signal Dm and the driving voltage line 172 may transmit a driving voltage ELVDD. The data signal Dm may have a different voltage level depending on an image signal inputted into the display device, and the driving voltage ELVDD may have a substantially constant level.

The transistors T1, T2, T3, T4, T5, T6, and T7 included in one pixel PX may include a first transistor T1, a second transistor T2, a third transistor T3, a fourth transistor T4, a fifth transistor T5, a sixth transistor T6, and a seventh transistor T7.

The first scan line 151 may transfer the scan signal GWn to the second transistor T2 and the third transistor T3, and the second scan line 152 may transfer the scan signal GIn to the fourth transistor T4. The third scan line 154 may transmit the scan signal GI(n+1) to the seventh transistor T7, and the control line 153 may transfer the light emission control signal EM to the fifth transistor T5 and the sixth transistor T6.

The gate electrode G1 of the first transistor T1 is connected to a first end of the storage capacitor Cst through a driving gate node GN, and a first electrode S1 of the first transistor T1 is connected to the driving voltage line 172 via the fifth transistor T5. A second electrode D1 of the first transistor T1 is connected to an anode of the light-emitting diode LED via the sixth transistor T6. According to an exemplary embodiment, the first electrode S1 of the first transistor T1 may also be connected to a first layer 31 to be described below. The first transistor T1 may receive the data signal Dm transferred by the data line 171 according to a switching operation of the second transistor T2 to supply a driving current to the light-emitting device diode LED.

The gate electrode G2 of the second transistor T2 is connected to the first scan line 151, and a first electrode S2 of the second transistor T2 is connected to the data line 171. A second electrode D2 of the second transistor T2 is connected to the first electrode S1 of the first transistor T1 and is connected to the driving voltage line 172 via the fifth transistor T5. The second transistor T2 may be turned on depending on the scan signal GWn received through the first scan line 151 to transfer the data signal Dm transferred from the data line 171 to the first electrode S1 of the first transistor T1.

A gate electrode G3 of the third transistor T3 is connected to the first scan line 151, and a first electrode S3 of the third transistor T3 is connected to the second electrode D1 of the first transistor T1 and is connected to the anode of the light emitting diode via the sixth transistor T6. A second electrode D3 of the third transistor T3 is connected to a second electrode D4 of the fourth transistor T4, the first end of the storage capacitor Cst, and the gate electrode G1 of the first transistor T1. The third transistor T3 may be turned on depending on the scan signal GWn transferred through the first scan line 151 to connect the gate electrode G1 and the second electrode D1 of the first transistor T1 to each other such that the first transistor T1 can be diode-connected.

A gate electrode G4 of the fourth transistor T4 is connected to the second scan line 152, and a first electrode S4 of the fourth transistor T4 is connected to a terminal of the initialization voltage Vint. The first electrode S4 of the fourth transistor T4 is connected to the second electrode D4 of the fourth transistor T4, the first end of the storage capacitor Cst, and the gate electrode G1 of the first transistor T1. The fourth transistor T4 is turned on in response to the scan signal GIn received through the second scan line 152 to transfer the initialization voltage Vint to the gate electrode G1 of the first transistor T1, in order to perform an initializing operation for initializing a voltage of the gate electrode G1 of the transistor T1.

A gate electrode G5 of the fifth transistor T5 is connected to the control line 153, and a first electrode S5 of the fifth transistor T5 is connected to the driving voltage line 172. A second electrode D5 of the fifth transistor T5 is connected to the first electrode S1 of the first transistor T1 and the second electrode D2 of the second transistor T2.

A gate electrode G6 of the sixth transistor T6 is connected to the control line 153, and a first electrode S6 of the sixth transistor T6 is connected to the first electrode S3 of the first transistor T1 and the first electrode S3 of the third transistor T3. A second electrode D6 of the sixth transistor T6 is electrically connected to the anode of the light-emitting diode. The fifth transistor T5 and the sixth transistor T6 may be simultaneously turned on in response to the emission control signal EM received through the control line 153, whereby the driving voltage ELVDD is compensated through the diode-connected first transistor T1 to be transferred to the light-emitting diode LED.

A gate electrode G7 of the seventh transistor T7 is connected to the third scan line 154, and a first electrode S7 of the seventh transistor T7 is connected to the second electrode D6 of the sixth transistor T6 and the anode of the light-emitting diode LED. A second electrode D7 of the seventh transistor T7 is connected to the terminal of the initialization voltage Vint terminal and the first electrode S4 of the fourth transistor T4.

The transistors T1, T2, T3, T4, T5, T6, and T7 may be p-type channel transistors such as PMOS transistors, but the present disclosure is not limited thereto, and at least one of the T1, T2, T3, T4, T5, T6, and T7 may be an n-type channel transistor. In addition, the first electrode and the second electrode described above are used to distinguish between two electrodes disposed at opposite sides of a channel, and the terms may be interchanged.

A second storage electrode E2 of the storage capacitor Cst is connected to the gate electrode G1 of the first transistor T1 as described above, and a first storage electrode E1 is connected to the driving voltage line 172. The cathode of a light-emitting diode LED is connected to a terminal of the common voltage ELVSS that transfers the common voltage ELVSS.

The structure of a pixel PX according to an exemplary embodiment is not limited to the structure illustrated in FIG. 1, and numbers of the transistors and capacitors included in one pixel PX and a connection relationship thereof may be variously modified.

The pixel PX of the display device according to an exemplary embodiment further includes a first layer 31 overlapping at least one of the transistors T1, T2, T3, T4, T5, T6, and T7 in a plan view. For example, the first layer 31 may overlap the first transistor T1. Particularly, the first layer 31 may overlap a channel of the first transistor T1.

FIG. 1 illustrates a circuit diagram of one pixel, and the first layer 31 which overlaps the first transistor T1 is illustrated by using a dotted line in order to facilitate understanding.

The first layer 31 may be electrically connected to the first electrode S1 to receive a same voltage as that of the first electrode S1. The first layer 31 may not only function as a light-blocking layer but also as a bottom gate of a dual gate structure. The first transistor T1 may have a bottom-gate structure by the first layer 31, so as to improve transistor reliability, whereby a leakage current decreases and driving capability becomes stronger, thereby reducing the power consumption of the display device.

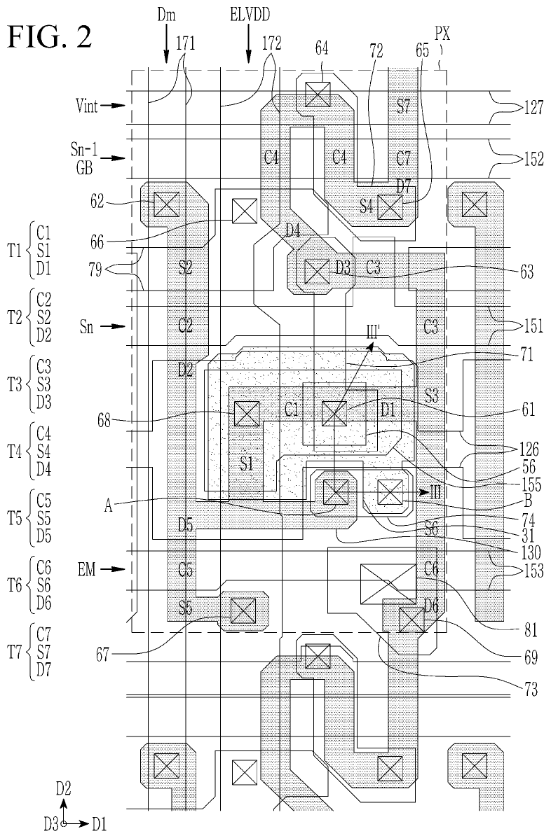

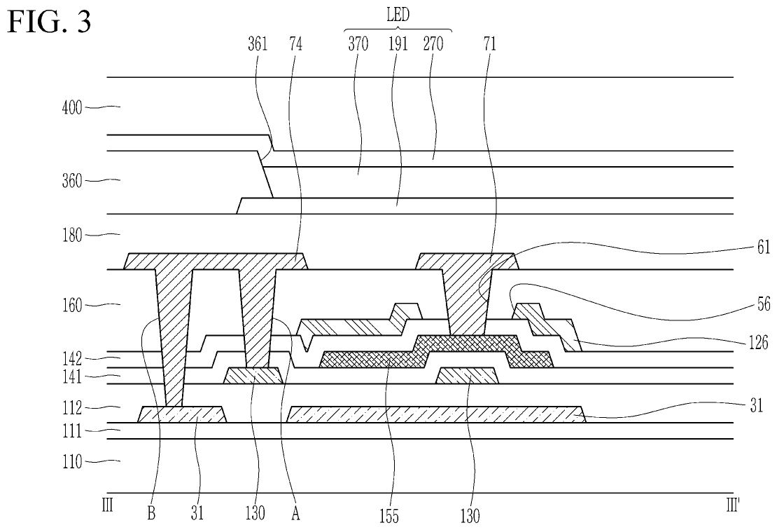

Hereinafter, a stacked structure of a display device according to an exemplary embodiment will be described with reference to FIG. 2 and FIG. 3 in addition to FIG. 1. FIG. 2 schematically illustrates a top plan view of a region of a display device according to an exemplary embodiment, and FIG. 3 illustrates a cross-sectional view taken along a line FIG. 2.

Referring to FIG. 2 as well as FIG. 1, the display device according to the present exemplary embodiment includes a scan line 151 extending along a first direction d1 to transfer a scan signal Sn, a previous-stage scan line 152 for transferring the scan signal S(n−1), a light emission control signal 153 for transferring the light emission control signal EM, and an initialization voltage line 127 for transferring the initialization voltage Vint. A bypass signal GB is transferred through the previous-stage scan line 152.

The light emitting diode display includes the data line 171 that extends in a second direction d2 that is orthogonal to the first direction d1 to transfer the data voltage Dm, and the driving voltage line 172 for transferring the driving voltage ELVDD.

The light emitting diode display includes a driving transistor, the first transistor T1, the second transistor T2, the third transistor T3, the fourth transistor T4, the fifth transistor T5, the sixth transistor T6, the seventh transistor T7, and the storage capacitor Cst and the light-emitting diode LED.

The semiconductor layer 130 may include channels C1, C2, C3, C4, C5, C6, and C7 of the first transistor T1, the second transistor T2, the third transistor T3, the fourth transistor T4, the fifth transistor T5, the sixth transistor T6, and the seventh transistor T7, respectively. The channels C1, C2, C3, C4, C5, C6, and C7 may be regions of the semiconductor layer 130. The channels C1, C2, C3, C4, C5, C6, and C7 may indicate regions between the first electrodes S1, S2, S3, S4, S5, S6, and S7 and the second electrodes D1, D2, D3, D4, D5, D6, and D7 in the semiconductor layer 130, respectively.

The first electrodes S1, S2, S3, S4, S5, S6, and S7 and the second electrodes D1, D2, D3, D5, D6, and D7 of the transistors T1, T2, T3, T4, T5, T6, and T7 are also disposed in the semiconductor layer 130. The first electrodes S1, S2, S3, S4, S5, S6, and S7 and second electrodes D1, D2, D3, D4, D5, D6, and D7 may indicate some regions of the semiconductor layer 130. The first electrodes S1, S2, S3, S4, S5, S6, and S7 and the second electrodes D1, D2, D3, D4, D5, D6, and D7 may be disposed at opposite sides of the aforementioned channels C1, C2, C3, C4, C5, C6, and C7.

Specifically, the channels C1, C2, C3, C4, C5, C6, and C7 include a region C1 of the semiconductor layer 130 where the semiconductor layer 130 and a first gate electrode 155 overlap each other, and may include regions C2 and C3 where the semiconductor layer 130 and the scan line 151 overlap each other, regions C4 and C7 where the semiconductor layer 130 and the previous-stage scan line 152 overlap each other, and regions C5 and C6 where the semiconductor layer 130 and the light emission control signal 153 overlap each other.

The semiconductor layer 130 (which is shaded in FIG. 2) may be bent in various shapes. The semiconductor layer 130 may include an oxide semiconductor or a polycrystalline semiconductor made of a polysilicon.

The semiconductor layer 130 may be disposed at opposite sides of the channels C1, C2, C3, C4, C5, C6, and C7 that are channel-doped with an n-type or p-type impurity, and a first doped region and a second doped region disposed at opposite sides of the channels C1, C2, C3, C4, C5, C6, and C7 to have a doping concentration that is higher than that of the impurity doped in the channels C1, C2, C3, C4, C5, C6, and C7. The first doped region and the second doped region respectively correspond to the first electrodes S1, S2, S3, S4, S5, S6, and S7 and the second electrodes D1, D2, D3, D4, D5, D6, and D7 of the transistors T1, T2, T3, T4, T5, T6, and T7. When one of the first doped region and the second doped region is a source region, the other doped region is a drain region. In addition, regions between the first electrodes and the second electrodes of different transistors may be doped in the semiconductor layer such that the transistors may be electrically connected to each other.

For example, the impurities to be doped into the channels C1, C2, C3, C4, C5, C6, and C7 may include phosphorus (P), arsenic (As), or antimony (Sb), or boron (B), aluminum (Al), indium (Al), and/or gallium (Ga). When the impurities include phosphorus, arsenic, antimony, or the like, the transistors may be n-type thin film transistors (TFTs) in which the electrons are carriers. When the impurities include boron, aluminum, indium, or gallium, the transistors may be n-type thin film transistors (TFTs) in which the holes are carriers.

Each channel of the transistors T1, T2, T3, T4, T5, T6, and T7 overlaps each gate electrode of the transistors T1, T2, T3, T4, T5, T6, and T7, and is disposed between the first electrodes S1, S2, S3, S4, S5, S6, and S7 and the second electrodes D1, D2, D3, D4, D5, D6, and D7 of the transistors T1, T2, T3, T4, T5, T6, and T7, respectively. The transistors T1, T2, T3, T4, T5, T6, and T7 may have substantially the same stacked structure. Hereinafter, the driving transistor T1 will be described in detail, and the remaining transistors T2, T3, T4, T5, T6, and T7 will be briefly described.

The first transistor Tl, which is a driving transistor, includes a first gate electrode 155, a first electrode S1, a second electrode D1, and a channel C1 disposed between the first electrode S1 and the second electrode D1. The channel C1 of the driving transistor T1 is disposed between the first electrode S1 and the second electrode D1 to overlap the first gate electrode 155 in a plan view. The channel C1 is bent in order to increase a length of the channel C1 in a limited region. As the length of the channel C1 becomes longer, a driving range of the gate voltage Vg applied to the first gate electrode 155 of the driving transistor T1 is widened and a driving current Id is constantly increased depending on the gate voltage Vg. As a result, it is possible to control a gray of light emitted from the light-emitting diode LED more minutely and to improve display quality of the light emitting diode display by adjusting a magnitude of the gate voltage Vg. In addition, since the channel extends in various directions rather than extending in one direction, there is an advantage that the effect of the orientation is offset in the manufacturing process, thereby reducing a process scattering influence. Accordingly, it is possible to prevent image quality deterioration such as a stain defect that may occur by a characteristic variation of the driving transistor T1 depending on regions of the display device due to process scattering (e.g., a luminance difference occurring depending on the pixel even when a same data voltage Dm is applied). A shape of such channels may be variously modified without being limited to the illustrated form.

The first gate electrode 155 overlaps the channel C1 of the first transistor T1 in a plan view. The first electrode S1 and the second electrode D1 are disposed on opposite sides of the channel C1, respectively. An insulated extension of a storage line 126 is disposed on the first gate electrode 155. The extension of the storage line 126 overlaps the gate electrode 155, with the second gate insulating layer 142 interposed therebetween in a plan view to constitute a storage capacitor Cst. The extension of the storage line 126 serves as a first storage electrode E1 of the storage capacitor Cst (see FIG. 1), and the first gate electrode 155 serves as a second storage electrode E2 (see FIG. 1). The extension of the storage line 126 has an opening 56 such that the first gate electrode 155 may be connected to a first data connecting member 71. In the opening 56, an upper surface of the first gate electrode 155 and the first data connecting member 71 are electrically connected to each other through a contact hole 61. The first data connecting member 71 is connected to the second electrode D3 of the third transistor T3 to connect the gate electrode 155 of the driving transistor T1 to the second electrode D3 of the third transistor T3. The first layer 31 to be described later may overlap the first transistor T1.

A gate electrode of the second transistor T2 may be a portion of the scan line 151. The data line 171 is connected to a first electrode S2 of the second transistor T2 through a contact hole 62. The first electrode S2 and the second electrode D2 may be portions of the semiconductor layer 130. A channel C2 of the second transistor T2 may be disposed between the first electrode S2 and the second electrode D2 in the semiconductor layer 130.

The third transistor T3 may be formed to include two transistors adjacent to each other. A channel C3 is illustrated at a left side and a lower side with reference to a portion where the semiconductor layer 130 is bent. These two parts each serve as channels C3 of the third transistor T3. A first electrode S3 of a first third transistor T3 is connected to a second electrode D3 of a second third transistor T3. A gate electrode of the two transistors T3 may be a portion of the scan line 151 or a portion that protrudes upward from the scan line 151. Such a structure may be referred to as a dual-gate structure, and may prevent a leakage current from flowing. The first electrode S3 of the third transistor T3 is connected to a first electrode S6 of the sixth transistor T6 and the second electrode D1 of the driving transistor T1. The second electrode D3 of the third transistor T3 is connected to the first data connecting member 71 through a contact hole 63.

The fourth transistor T4 is formed to include two fourth transistors T4, and the two fourth transistors T4 are formed at a portion where the previous-stage scan line 152 and the semiconductor layer 130 meet each other. A gate electrode of the second transistor T2 may be a portion of the previous-stage scan line 152. A first electrode S4 of a first fourth transistor T4 is connected to a second electrode D4 of a second fourth transistor T4. Such a structure may be referred to as a dual gate structure, and may prevent a leakage current from flowing. A second data connection member 72 is connected to the first electrode S4 of the fourth transistor T4 through a contact hole 65, and the first data connection member 71 is connected to the second electrode D2 of the fourth transistor T4 through the contact hole 63.

As such, a dual-gate structure may be used by using the third transistor T3 and the fourth transistor T4 to effectively prevent occurrence of leakage current by blocking an electron movement path of the channel in an off state.

A gate electrode of the fifth transistor T5 may be a portion of the light emission control signal 153. The driving voltage line 172 is connected to a first electrode S5 of the fifth transistor T5 through a contact hole 67, and a second electrode D5 is connected to the first electrode S1 of the driving transistor T1 through the semiconductor layer 130.

A gate electrode of the sixth transistor T6 may be a portion of the light emission control signal 153. The third data connection member 73 is connected to a second electrode D6 of the sixth transistor T6 through a contact hole 69, and a first electrode S6 is connected to the second electrode D1 of the driving transistor through the semiconductor layer 130.

A gate electrode of the seventh transistor T7 may be a portion of the previous-stage scan line 152. A first electrode S7 of the seventh transistor T7 is connected to the second electrode D6 of the sixth transistor T6, and a second electrode D7 is connected to the first electrode S4 of the fourth transistor T4.

The storage capacitor Cst includes a first storage electrode E1 and a second storage electrode E2 which overlap each other, with a second gate insulating layer 142 interposed therebetween. The second storage electrode E2 may correspond to the first gate electrode 155 of the driving transistor T1, and the first storage electrode E1 may be the extension of the storage line 126. Herein, the second gate insulating layer 142 serves as a dielectric material, and a capacitance is determined by the voltage charged in the storage capacitor Cst and a voltage between the first and second storage electrodes E1 and E2. It is possible to secure a space in which the storage capacitor Cst can be formed in the space that is narrowed by the channel of the driving transistor T1 occupying a large area within the pixel by using the first gate electrode 155 as the second storage electrode E2.

The driving voltage line 172 is connected to the first storage electrode E1 or 126 through a contact hole 68. Accordingly, the storage capacitor Cst stores a charge corresponding to a difference between the driving voltage ELVDD transferred to the first storage electrode E1 through the driving voltage line 172 and the gate voltage Vg of the gate electrode 155.

A second data connecting member 72 is connected to the initialization voltage line 127 through a contact hole 64. A pixel electrode, which will be described later, may be connected to a third data connecting member 73 through a contact hole 81.

A parasitic capacitor control pattern 79 may be disposed between the dual gate electrodes of the third transistor T3. A parasitic capacitor exists in the pixel, and an image quality characteristic thereof may vary when a voltage applied to the parasitic capacitor changes. The driving voltage line 172 is connected to the parasitic capacitor control pattern 79 through a contact hole 66. As a result, the image quality characteristic may be prevented from being varied by applying the driving voltage ELVDD having a constant DC voltage to the parasitic capacitor. The parasitic capacitor control pattern 79 may be disposed in a different region than the illustrated position, and a voltage other than the driving voltage ELVDD may be applied thereto.

A first end of the first data connecting member 71 is connected to the gate electrode 155 through the contact hole 61, and a second end thereof is connected to the second electrode D3 of the third transistor T3 and the second electrode D4 of the fourth transistor T4 through the contact hole 63.

A first end of the second data connecting member 72 is connected to the first electrode S4 of the fourth transistor T4 through the contact hole 65, and a second end thereof is connected to the initialization voltage line 127 through the contact hole 64.

The third data connecting member 73 is connected to the second electrode D6 of the sixth transistor T6 though the contact hole 69.

A fourth data connection member 74 may be connected to the semiconductor layer 130 extending from the first electrode S1 of the first transistor T1 through a contact hole A, and may be connected to the first electrode 31 through a contact hole B.

Hereinafter, a cross-sectional structure of a display device according to an exemplary embodiment will be described depending on a stacking order thereof with reference to FIG. 3 as well as FIG. 2. The description of the same contents as those described in FIG. 2 will be omitted.

The display device according to the present exemplary embodiment includes a substrate 110. The substrate 110 may include a plastic layer and a barrier layer. The plastic layer and the barrier layer may be alternately stacked.

The plastic layer may be made of a material selected from the group consisting of polyethersulphone (PES), polyacrylate (PAR), polyetherimide (PEI), polyethylene naphthalate (PEN), polyethylene terephthalate (PET) (PPS), polyarylate, polyimide (PI), polycarbonate (PC), poly(arylene ether sulfone), and combinations thereof.

The barrier layer may include at least one of a silicon oxide, a silicon nitride, and an aluminum oxide, and may include any inorganic material without limitation.

A first buffer layer 111 is disposed on the substrate 110. The first buffer layer 111 may include an inorganic insulating material such as a silicon oxide, a silicon nitride, or an aluminum oxide, or an organic insulating material such as a polyimide or a polyacryl.

The first buffer layer 111 may prevent impurities from flowing into the transistor and flatten one surface of the substrate 110. According to an exemplary embodiment, the first buffer layer 111 may be omitted.

The first layer 31 is disposed on the buffer layer 111. The first layer 31 can have conductivity. The first layer 31 may include a metal having conductivity, or a semiconductor material having a conductive characteristic that is similar thereto. The metal may include, e.g., molybdenum, chromium, tantalum, titanium, copper, or an alloy thereof. The first layer 31 may be a single layer or a multilayer.

The first layer 31 may overlap the first transistor T1, particularly the channel C1 of the first transistor T1, according to an exemplary embodiment. The first layer 31 may overlap not only the channel C1 of the first transistor T1 but also the first electrode S1 and the second electrode D1 disposed at opposite sides of the channel C1.

The first layer 31 may completely overlap the gate electrode 155 in a plan view, and may have a region that protrudes to be connected to another layer. The first layer 31 may have any form of overlapping the first transistor T1 and is not limited to the above contents.

The first layer 31 prevents light from reaching the first transistor T1, thereby preventing deterioration of channel characteristics of the transistor such as a leakage current. The first layer 31 may also serve as a bottom gate of the first transistor T1 by receiving a predetermined voltage. The bottom-gate structure may be formed by the first layer 31 so as to improve transistor reliability, whereby a leakage current decreases and driving capability becomes stronger, thereby reducing the power consumption of the display device.

A second buffer layer 112 is disposed on the substrate 31. The second buffer layer 112 may include an inorganic insulating material such as a silicon oxide, a silicon nitride, or an aluminum oxide, or an organic insulating material such as polyimide or a polyacryl.

The semiconductor layer 130 including the channels C1, C2, C3, C4, C5, C6, and C7, the first electrodes S1, S2, S3, S4, S5, S6, and S7, and the second electrodes D1, D2, D3, D4, D5, D6, and D7 of the transistors T1, T2, T3, T4, T5, T6, and T7 is disposed on the second buffer layer 112. The detailed contents are the same as described above, and thus will be omitted.

A portion of the semiconductor layer 130 may be connected to the first layer 31. For example, the first electrode S1 of the first transistor T1 includes a region extending in the first direction d1, and the region and the first layer 31 may be electrically connected. The region extending from the first electrode S1 of the first transistor T1 may receive the same voltage as the first electrode S1.

A first gate insulating layer 141 covering the semiconductor layer 130 is disposed on the semiconductor layer 130. A first gate conductor including the first gate electrode 155, the scan line 151, the previous-stage scan line 152, and the light emission control signal 153 is disposed on the first gate insulating layer 141.

The second gate insulating layer 142 covering the first gate conductor is disposed on the first gate conductor. The first gate insulating layer 141 and the second gate insulating layer 142 may include an inorganic insulating material such as a silicon nitride, a silicon oxide, and an aluminum oxide.

A second gate conductor including the storage line 126 having the opening 56, the initialization voltage line 127, and the parasitic capacitor control pattern 79 is disposed on the second gate insulating layer 142.

A first insulating layer 160 covering the second gate conductor is disposed on the second gate conductor. The first insulating layer 160 may include an inorganic insulating material such as a silicon nitride, a silicon oxide, and an aluminum oxide, or an organic insulating material.

A data conductor including the data line 171, the driving voltage line 172, the first data connecting member 71, the second data connecting member 72, the third data connecting member 73, and the fourth data connecting member 74 is disposed on the first insulating layer 160.

According to an exemplary embodiment, the fourth data connecting member 74 may be connected to a portion of the semiconductor layer 130 through the contact hole A. Particularly, referring to FIG. 2, the fourth data connection member 74 may be connected to the semiconductor layer 130 extending from an end of the first electrode S1 of the first transistor T1 in the first direction d1.

The fourth data connecting member 74 may also be connected to the first layer 31 through the contact hole B. The first layer 31 and the semiconductor layer 130 may be connected to each other through the fourth data connecting member 74.

The first layer 31 may receive a voltage applied to the semiconductor layer 130, for example, a voltage applied to the first electrode S1 through the fourth data connecting member 74.

A second insulating layer 180 covering the data conductor is disposed on the data conductor. The second insulating layer 180 may be a planarization layer, and may include an organic insulating material or an inorganic insulating material.

A pixel electrode 191 is disposed on the second insulating layer 180. The pixel electrode 191 is connected to the third data connection member 73 through the contact hole 81 as illustrated in FIG. 2.

A partition wall 360 is disposed on the second insulating layer 180 and the pixel electrode 191. The partition wall 360 has an opening 361 overlapping the pixel electrode 191. An emission layer 370 is disposed in the opening 361. A common electrode 270 overlapping a front surface of the substrate 110 is disposed on the light emitting layer 370 and the partition wall 360. The pixel electrode 191, the emission layer 370, and the common electrode 270 constitute a light-emitting diode LED.

According to another example embodiment, the pixel electrode may be an anode, which is a hole injection electrode, and the common electrode may be a cathode, which is an electron injection electrode. Conversely, the pixel electrode may be the cathode, and the common electrode may be the anode. When holes and electrons are injected from the pixel electrode and the common electrode into the emission layer, excitons formed by combining the injected holes and electrons are emitted when they fall from an excited state to a ground state.

An encapsulation layer 400 for protecting the light-emitting diode LED is disposed on the common electrode 270. The encapsulation layer 400 may be in contact with the common electrode 270, as illustrated therein, and may be spaced from the common electrode 270 according to an exemplary embodiment.

The encapsulation layer 400 may be a thin film encapsulation layer in which an organic film and an inorganic layer are stacked, and may include a triple layer including an inorganic film, an organic layer, and an inorganic layer. According to an exemplary embodiment, a capping layer and a functional layer may be disposed between the common electrode 270 and the encapsulation layer 400.

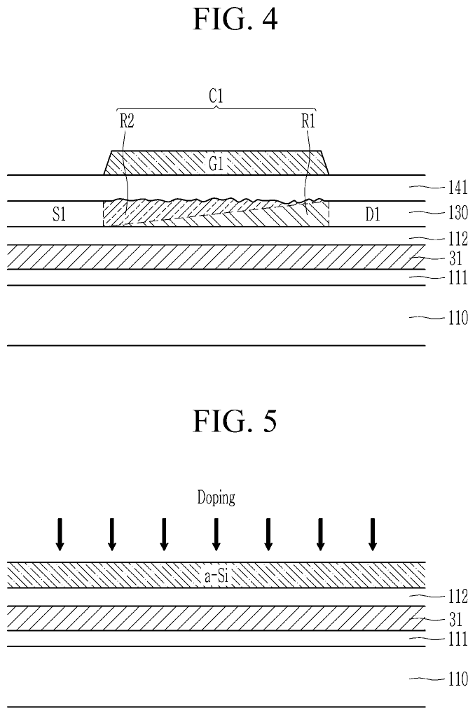

Hereinafter, the semiconductor layer 130 according to an exemplary embodiment will be described in more detail with reference to FIG. 4. FIG. 4 illustrates an enlarged schematic cross-sectional view of some constituent elements of FIG. 3.

Referring to FIG. 4, the channel C1 of the semiconductor layer 130 overlapping the first layer 31 may include a depletion region R1 and a carrier transport region R2. The depletion region R1 may be disposed at a lower end of the semiconductor layer 130, and the carrier transport region R2 may be disposed at an upper end of the semiconductor layer 130.

The depletion region R1 is a region in which carrier transport is not relatively performed, and the carrier transport region R2 may be referred to as a region in which the carrier transport is actively performed.

Cross-sections of the depletion region R1 and the carrier transport region R2 may have a shape that is inclined toward the substrate 110. A thickness of the depletion region R1 may vary. For example, the depletion region R1 close to the first electrode S1 may be thin, and the carrier transport region R2 close to the second electrode D1 may be thick. A thickness of the carrier transport region R2 may vary. For example, the carrier transport region R2 close to the first electrode S1 may be thick, and the carrier transport region R2 close to the second electrode D1 may be thin.

As an area occupied by the depletion region R1 in the semiconductor layer 130 is increased, an area in which carriers can move in the channel C1 of the semiconductor layer 130 is reduced. In this case, a number of carriers trapped in the channel C1 decreases, and a number of carriers per unit area moving from the first electrode S1 to the second electrode D1 may increase. That is, the carrier transport effect may be improved.

When a predetermined voltage is applied to the first layer 31, the first layer 31 forms an electric field with the first electrode S1 and the second electrode D1 of the semiconductor layer 130, thereby reducing the leakage current.

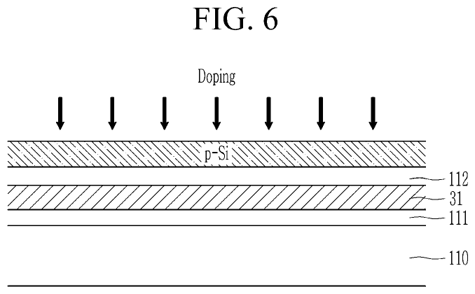

Hereinafter, a manufacturing method of a semiconductor layer according to an exemplary embodiment will be described with reference to FIG. 5 and FIG. 6. FIG. 5 illustrates a cross-sectional view showing a step of a manufacturing process of a display device according to an example, and FIG. 6 illustrates a cross-sectional view showing a step of a manufacturing process of a display device according to a comparative example.

Referring to FIG. 5, an amorphous silicon layer a-Si is formed on a second buffer layer 112.

A channel according to the example may include an impurity, and thus an impurity doping process may be performed on the amorphous silicon layer a-Si.

Examples of impurities to be doped into the amorphous silicon layer a-Si may include phosphorus (P), arsenic (As), antimony (Sb), boron (B), aluminum (Al), indium (Al), and the like. When the impurities include phosphorus, arsenic, antimony, and the like, the transistors may be n-type thin film transistors (TFTs) in which the electrons are carriers. When the impurities include boron, aluminum, indium, or gallium, the transistors may be n-type thin film transistors (TFTs) in which the holes are carriers.

Thereafter, the amorphous silicon layer a-Si doped with impurities is irradiated with a laser to perform a crystallization process. A kind of laser may be an excimer laser. The excimer laser is a gas laser using a molecule called an excimer, such as ArF, KrF, XeCl, etc., which may have single wavelength and high power.

A first side of the amorphous silicon layer a-Si may be damaged during impurity doping. However, defects included in the semiconductor layer can be healed by the crystallization process by performing the laser crystallization process after doping the impurity. In addition, since the crystallization process is performed in a state where the impurities are stably injected on the semiconductor layer, a carrier concentration included in the semiconductor layer may be increased, and thus a characteristic of the semiconductor layer may be improved.

Referring to FIG. 6 according to the comparative example, after the amorphous silicon layer is formed, a laser crystallization process is performed to form a polycrystalline silicon layer p-Si. Thereafter, an impurity doping process is performed on the polycrystalline silicon layer p-Si. According to this impurity doping process, surface damage of the semiconductor layer may occur, which may deteriorate the reliability of the semiconductor layer.

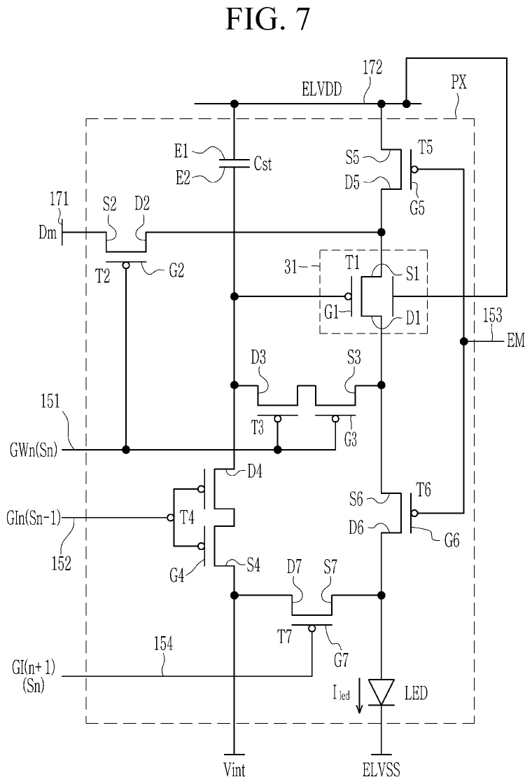

Hereinafter, driving of a pixel will be described with reference to FIG. 7. FIG. 7 illustrates a circuit diagram of a pixel of a display device according to an exemplary embodiment. A description of same constituent elements as the constituent elements described above will be omitted.

The first layer 31 according to the present exemplary embodiment may receive a constant voltage, for example, the driving voltage ELVDD.

The first layer 31 may have a light blocking function for the channel of at least one of the overlapping transistors T1, T2, T3, T4, T5, T6, and T7 to prevent leak current occurrence and characteristic deterioration of the transistors T1, T2, T3, T4, T5, T6, and T7. For example, when the driving voltage ELVDD is constantly applied to the first layer 31, a potential of the first layer 31 may be constantly maintained, thereby preventing it from affecting the surrounding electrodes. When the first layer 31 overlaps the first transistor T1, the first transistor T1 may have a high data range, so that deviations of variations in a gate-source voltage Vgs and in the output depending on characteristic deviation may be reduced, thereby improving display characteristics of the display device.

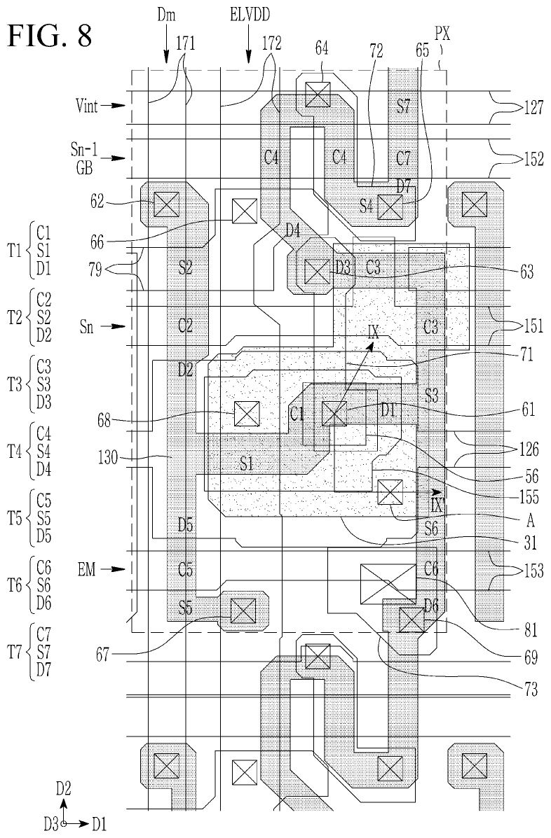

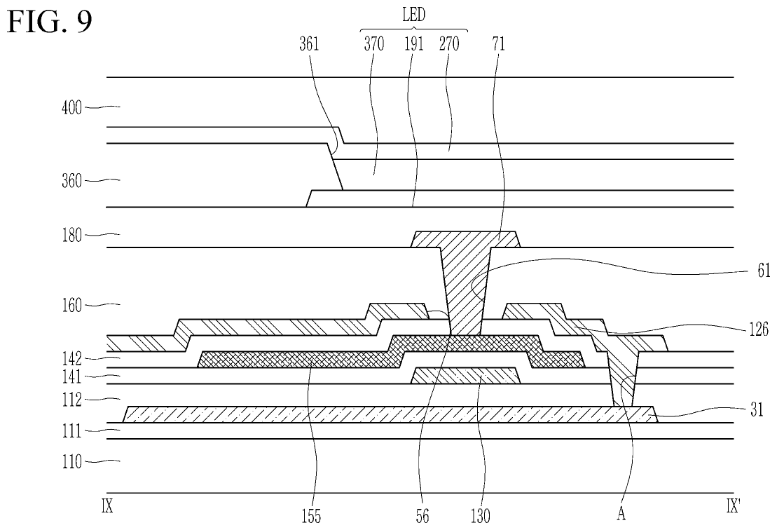

A display device according to an exemplary embodiment will now be described with reference to FIG. 8 and FIG. 9. FIG. 8 schematically illustrates a top plan view of a region of a display device according to an exemplary embodiment, and FIG. 9 illustrates a cross-sectional view taken along a line IX-IX′ of FIG. 8. In the exemplary embodiment of FIG. 8 and FIG. 9, a description of same constituent elements as the constituent elements described above will be omitted.

Referring to FIG. 8, according to the present exemplary embodiment, the first layer 31 may overlap the first transistor T1. In particular, the first layer 31 may overlap the channel C1, the first electrode S1, and the second electrode D1 of the first transistor T1.

The first layer 31 may also overlap the third transistor T3 according to an exemplary embodiment. Particularly, the first layer 31 may overlap the channel C3 of the third transistor T3. However, the first layer 31 may have a form overlapping only the first transistor T1 as in the exemplary embodiment of FIG. 2 without being limited to this exemplary embodiment.

The first layer 31 may be connected to the extension of the storage line 126 through the contact hole A. The driving voltage line 172 is connected to the storage line 126 through the contact hole 68. The driving voltage ELVDD may be applied to the storage line 126. The driving voltage ELVDD may be applied to the first layer 31 through the storage line 126.

When the driving voltage ELVDD is constantly applied to the first layer 31, a potential of the first layer 31 may be constantly maintained, thereby preventing it from affecting the surrounding electrodes. According to an example embodiment, when the first layer 31 overlaps the first transistor T1, the first transistor T1 may have a high data range, so that deviations of variations in a gate-source voltage Vgs and in the output depending on characteristic deviation may be reduced, thereby improving display characteristics of the display device.

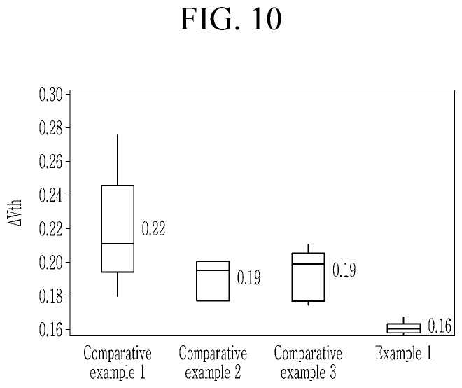

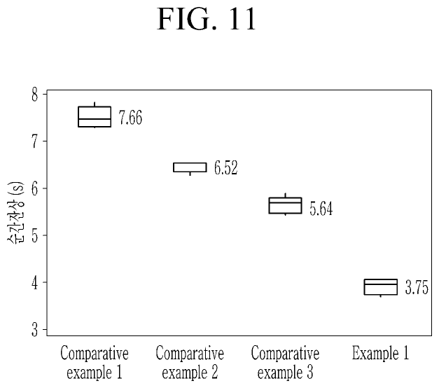

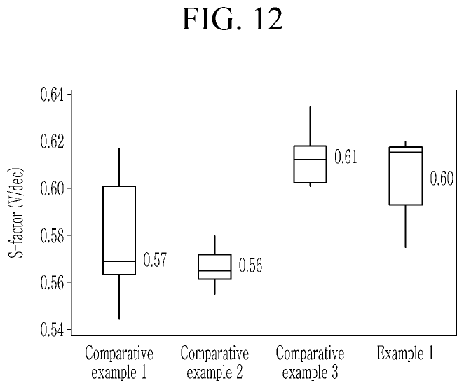

Hereinafter, characteristics according to examples and comparative examples will be described with reference to FIG. 10 to FIG. 12. FIG. 10 illustrates a graph showing hysteresis characteristics for a comparative example and an example, FIG. 11 illustrates a graph showing afterimage characteristics for a comparative example and an example, and FIG. 12 illustrates a graph showing S-factors for a comparative example and an example.

In FIG. 10 to FIG. 12, Example 1 is a display device having a structure including a first layer and a channel having an impurity, and Comparative Example 1 is a display device having a structure including neither the first layer nor the channel having an impurity. Comparative Example 2 is a display device having a structure including the channel having an impurity, and Comparative Example 3 is a display device having a structure including the first layer.

First, referring to FIG. 10, Comparative Example 1 has a value of about 0.22, Comparative Example 2 has a value of about 0.19, Comparative Example 3 has a value of about 0.19, and Example 1 has a value of about 0.16. The hysteresis characteristic of Example 1 was improved by decreasing by 0.06 as compared with Comparative Example 1, and the Example 1 has a low level of hysteresis characteristic as compared with Comparative Example 2 and Comparative Example 3.

For a time for measuring the afterimage is illustrated in FIG. 11, Comparative Example 1 shows about 7.66 s, Comparative Example 2 shows about 6.52 s, Comparative Example 3 shows about 5.64 s, and Example 1 shows about 3.75 s. It is seen that an instantaneous afterimage effect is the best according to the example.

Referring to FIG. 10 and FIG. 11, the display device including the first layer and the channel having an impurity needs to be provided in order to ameliorate the instantaneous afterimage while improving the hysteresis characteristic. The hysteresis characteristic indicates that the smaller the value is, the easier the current control is.

In addition, the instantaneous afterimage and the threshold voltage according to the doping concentration of the impurity doped into the channel will be described with reference to Table 1. Condition 1 is a case where the channel is not doped with an impurity, Condition 2 is a case where the impurity is doped at a 5*10¹¹ concentration, Condition 3 is a case where the impurity is doped at a 7.5*10¹¹ concentration, Condition 4 is a case where the impurity is doped at a 1*10¹² concentration, Condition 5 is a case where the impurity is doped at a 1.5*10¹² concentration, and Condition 6 is a case where the impurity is doped at a 2*10¹² concentration.

In this case, Condition 4 and Condition 5 are satisfied when a time for which the afterimage is observed is less than 6 s and the threshold voltage value required for the display device is satisfied. Based on following conditions, the impurity concentration doped into the channel according to an exemplary embodiment is in a range between 7.5*10¹¹ and 2*10¹², exclusive.

TABLE 1

| | Instantaneous afterimage (s) | Vth (V) |
|---|---|---|
| Condition 1 | 7.5 | −3.30 |
| Condition 2 | 8.0 | −3.83 |
| Condition 3 | 6.4 | −3.45 |
| Condition 4 | 5.7 | −3.30 |
| Condition 5 | 4.7 | −2.80 |
| Condition 6 | 6.4 | −2.6 |

Referring to FIG. 12 showing S-factor, Example 1 has a value of about 0.60, Comparative Example 1 has a value of about 0.57, Comparative Example 2 has a value of about 0.56, and Comparative Example 1 has a value of about 0.61. It may be advantageous for the driving transistor to have a relatively large S-factor in order to reduce the luminance deviation due to the scattering of the gate voltage. Herein, the term “S-factor” represents the current-voltage characteristic of a transistor, which indicates the gate voltage needed to increase the drain current by ten times when a gate voltage that is equal to or lower than the threshold voltage is applied. The S-factor is often referred to as a “sub-threshold slope”.

It is seen that when the first layer and the impurity-doped channel were included according to Example 1, the S-factor was superior to the increase of the depletion region and the carrier concentration of the channel.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### Description of Symbols

110: substrate

130: semiconductor layer

LED: light-emitting diode

31: first layer

What is claimed is:

1. A display device comprising:
a substrate;
a semiconductor layer disposed on the substrate;
a first transistor including a first gate electrode disposed on the semiconductor layer;
a light-emitting diode connected with the first transistor; and
a first layer disposed between the substrate and the semiconductor layer,
wherein the semiconductor layer includes
a first electrode, a second electrode, and a channel disposed between the first electrode and the second electrode,
the channel includes an impurity, and
the first layer overlaps the first transistor.

2. The display device of claim 1, wherein
the first layer is connected to one of the first electrode and the second electrode.

3. The display device of claim 1,
further comprising:
an insulating layer disposed on the first transistor; and
a data connecting member disposed on the insulating layer,
wherein the first electrode and the first layer are connected with each other by the data connecting member.

4. The display device of claim 1, wherein
the impurity includes one of boron, aluminum, indium, and gallium.

5. The display device of claim 1, wherein
the first layer includes one of a metal having a conductive characteristic and a semiconductor material having a conductive characteristic that is similar to that of a metal.

6. The display device of claim 1, wherein
the semiconductor layer includes a protrusion.

7. The display device of claim 1, wherein
the channel includes a depletion region and a carrier transport region, and
the depletion region is disposed at a lower end of the channel, and the carrier transport region is disposed at an upper end of the channel.

8. The display device of claim 7, wherein
cross-sections of the depletion region and the carrier transport region have shapes that are inclined with reference to the substrate.

9. A display device comprising:
a substrate;
a semiconductor layer disposed on the substrate;
a first transistor including a first gate electrode disposed on the semiconductor layer;
a light-emitting diode connected with the first transistor; and
a first layer disposed between the substrate and the semiconductor layer,
wherein the semiconductor layer includes a first electrode, a second electrode, and a channel disposed between the first electrode and the second electrode,
the channel includes an impurity, and
the first layer receives a constant voltage.

10. The display device of claim 9, wherein
the first layer receives a driving voltage.

11. The display device of claim 9, further comprising
a storage line configured to overlap the first gate electrode, and
the storage line and the first layer are connected to each other.

12. The display device of claim 11, wherein
the first layer receives a constant voltage.

13. The display device of claim 9, further comprising
a gate insulating layer disposed between the storage line and the first gate electrode, and
the storage line and the first layer constitute a storage capacitor.

14. The display device of claim 9,
further comprising:
an insulating layer disposed on the first transistor; and
a driving voltage line disposed on the passivation layer,
wherein the driving voltage line is connected to the storage line through a contact hole.

15. The display device of claim 9,
further comprising a second transistor and a third transistor connected to the first transistor, and
the first layer overlaps the third transistor.

16. The display device of claim 9, wherein
the impurity includes at least one of boron, aluminum, indium, and gallium.

17. The display device of claim 9, wherein
the first layer includes one of a metal having a conductive characteristic and a semiconductor material having a conductive characteristic that is similar to that of a metal.

18. The display device of claim 9, wherein
the semiconductor layer includes a protrusion.

19. The display device of claim 9, wherein
the channel includes the depletion region and a carrier transport region, and
the depletion region is disposed at a lower end of the channel, while the carrier transport region is disposed at an upper end of the channel.

20. The display device of claim 19, wherein
cross-sections of the depletion region and the carrier transport region have shapes that are inclined with reference to the substrate.
